(19) United States
(12) Patent Application Publication
(10) Pub. No.: US 2002/0140052 A1
(43) Pub. Date: Oct. 3, 2002

(54) High frequency semiconductor device

(75) Inventors: Yutaka Mimino, Yamanashi (JP); Osamu Baba, Yamanashi (JP); Yoshio Aoki, Yamanashi (JP); Muneharu Gotoh, Yamanashi (JP)

Correspondence Address: ARMSTRONG,WESTERMAN & HATTORI, LLP, 1725 K STREET, NW., SUITE 1000, WASHINGTON, DC, 20006, US

(73) Assignee: Fujitsu Quantum Devices Limited, Nakakoma-gun (JP)

(21) Appl. No.: 10/085,035

(22) Filed: Mar. 1, 2002

(30) Foreign Application Priority Data
Mar. 30, 2001 (JP) 2001-99960

(51) Int. Cl. H01L 29/00

(52) U.S. Cl. 257/531

(57) ABSTRACT

A high frequency semiconductor device has at least one gap which is formed by removing part of a ground plate under an inductor. By forming the gap, a parasitic capacitance which is caused by a dielectric layer between the ground plate and the ground potential can be deleted.

### BACKGROUND OF THE INVENTION

1. Field of the Invention

The present invention relates to a general type of monolithic microwave integrated circuit (MMIC) in which a waveguide for high frequency signals is used.

2. Description of the Related Art

For an MMIC which uses high speed semiconductor elements such as high-electron-mobility transistors (HEMTs) and hetero-bipolar transistors (HBTs), it is necessary to use a high frequency waveguide as a wiring line differently from an ordinary silicon integrated circuit because the MMIC processes high frequency signals. A microstrip line which has stable line characteristics and weak dispersion characteristics, which means that frequency dependency of a transmission constant is weak, is used as the high frequency waveguide. The MMIC needs an inductor as a passive element. Basically, an inductor in which the microstrip line is used, is employed.

FIG. 1 is a plan view of an inductor according to the related art in which a microstrip line is used. FIG. 2 shows a cross-section taken along the line II-II of FIG. 1.

FIG. 1 shows a meander type of inductor 100. The inductor 100 has a shape in which a line conductor 1 meanders. Line conductors 200 are connected to the ends of the line conductor 100.

Referring to FIG. 2, the inductor 100 has a base portion composed of, for example, gallium arsenide (GaAs). In the inductor 100, a semiconductor substrate 2 on which an active element (not shown) is formed is covered with a surface insulating layer 3 for protecting the surface of the semiconductor substrate 2. A ground plate 4 connected to the ground potential, and an insulating interlayer 5 composed of an insulating resin material, etc., are provided above the surface insulating layer 3. The line conductor 1 is provided on the surface of the insulating interlayer 5. The line conductor 1 combines with the ground plate 4 to form a strip line.

The inductor 100 shown in FIGS. 1 and 2 has a structure in which part of the line conductor 1 simply meanders, and can easily obtain a desired inductance. Since the inductor 100 has a parasitic capacitance, the parasitic capacitance must be taken into consideration in high frequency design.

The reason that the inductor 100 has the parasitic capacitance is that the inductor 100 is formed by simply deforming the line conductor 1 (to meander, etc.).

The line conductor 1 combines with the ground plate 4 to form a transmission line, whereby desired transmission characteristics are obtained. Thus, when this is used to form the inductor 100, the parasitic capacitance is formed by a combination of the line conductor 1 and the insulating interlayer 5 formed between the line conductor 1 and the ground plate 4.

### SUMMARY OF THE INVENTION

It is an object of the present invention to provide an inductor having a small parasitic capacitance.

To this end, according to the present invention, the above object is achieved through provision of a high frequency semiconductor device including a semiconductor substrate, a ground plate provided on the semiconductor substrate, at least one insulating interlayer, a line conductor provided above the ground plate, with the at least one insulating interlayer provided therebetween, and at least one inductor as a conductive layer which is connected to the line conductor and, under which at least one gap is formed by removing part of the ground plate.

Preferably, a conductive layer forming the insulator is linear.

A conductive layer forming the insulator may have a bending form obtained by combining linear shapes.

A conductive layer forming the insulator may meander.

A conductive layer forming the insulator may have a spiral pattern.

Part of the line conductor may be led outward from the spiral pattern by air bridging.

Part of the line conductor may be led outward from the spiral pattern by a multilayered wiring structure in which the line conductor is multilayered, with the insulating interlayers provided therebetween.

The high frequency semiconductor device may further include at least one throughhole, and part of the line conductor in the center of the spiral pattern may be led to the lower side of the spiral pattern by the at least one throughhole.

The inductors may be connected in series to form a filter.

The line conductor may be linear, and the line conductor with the gaps formed in the ground plate may constitute the inductors.

The at least one insulating interlayer may be made of an insulating resin material.

The insulating resin material may be one of polyimide and benzocyclobutene.

The line conductor may be multilayered, with the insulating interlayers provided therebetween.

As described above, according to the present invention, the ground potential does not exist under an inductor. Therefore, a parasitic capacitance caused by a dielectric layer between the inductor and the ground potential can be eliminated, so that a high frequency semiconductor device having superior characteristics can be obtained.

### BRIEF DESCRIPTION OF THE DRAWINGS

FIG. 1 is a plan view showing an inductor according to the related art;

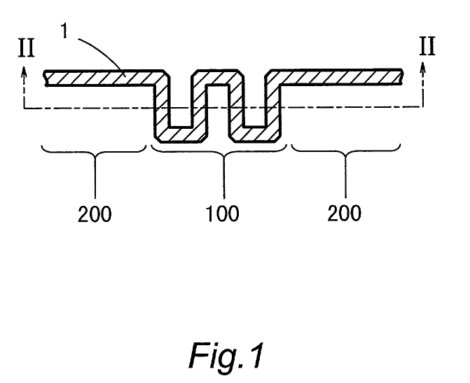

FIG. 2 is a cross-sectional view taken along the line II-II of FIG. 1;

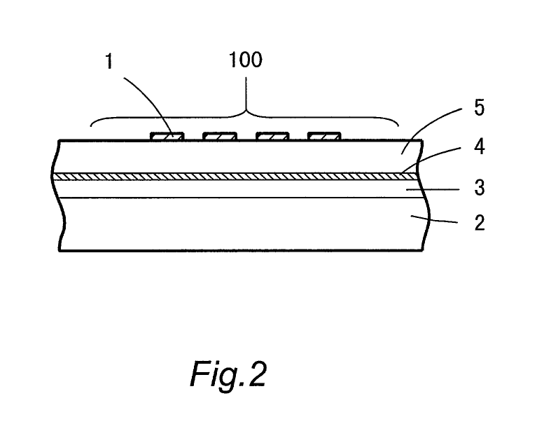

FIG. 3 is a plan view showing the principle of the present invention;

FIG. 4 is a cross-sectional view taken along the line IV-IV of FIG. 3;

FIG. 5 is a plan view showing an inductor according to a first embodiment of the present invention;

FIG. 6 is a cross-sectional view taken along the line VI-VI of FIG. 5;

FIG. 7 is a plan view showing an inductor according to a second embodiment of the present invention;

FIG. 8 is a plan view showing inductors according to a third embodiment of the present invention; and

FIG. 9 is a cross-sectional view taken along the line IX-IX of FIG. 8;

### DESCRIPTION OF THE PREFERRED EMBODIMENTS

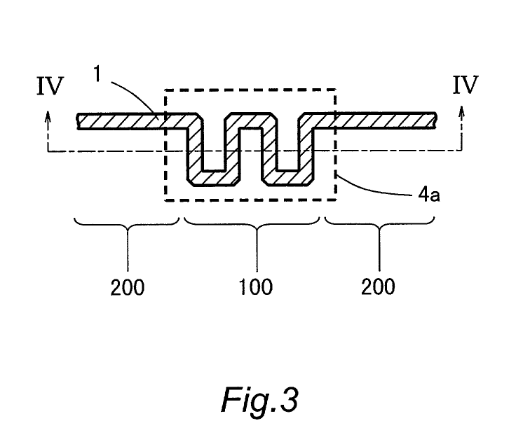

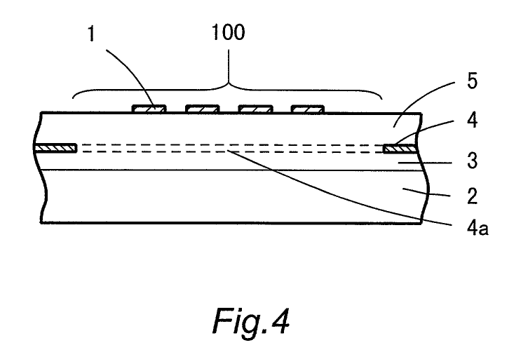

The principle of the present invention is described below with reference to FIGS. 3 and 4. FIG. 3 is a plan view of the principle of the present invention. FIG. 4 is a cross-section taken along the line IV-IV of FIG. 3.

In the present invention, to delete the parasitic capacitance, a gap 4a is formed without providing the ground plate 4 in FIGS. 3 and 4 which are positioned under the region of an inductor 100.

By forming the gap 4a, the ground potential cannot exist under the inductor 100. This deletes a parasitic capacitance caused by a dielectric layer (an insulating interlayer 5) formed between a line conductor 1 and the ground potential.

The inductor 100 in FIGS. 3 and 4 is not opposed to the ground plate 4. Accordingly, the inductor 100 is electrically regarded as a lumped constant circuit.

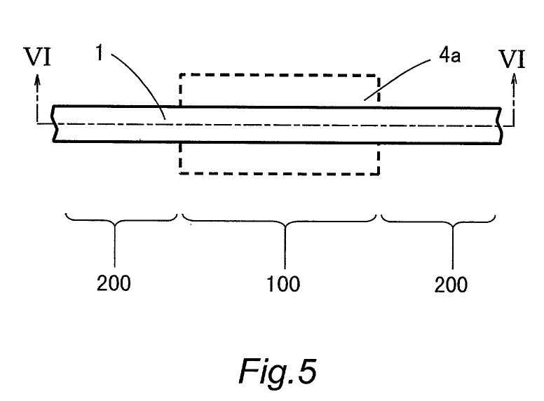

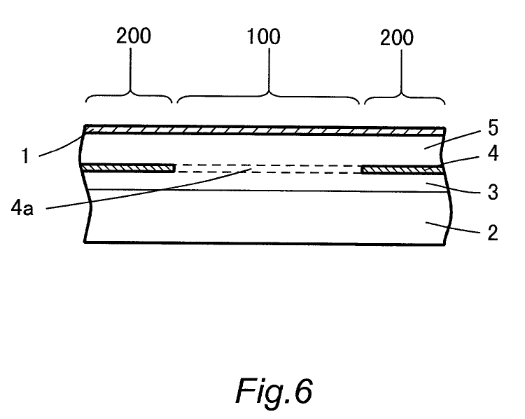

Referring to FIGS. 5 and 6, an inductor according to a first embodiment of the present invention is described below. FIG. 5 is a plan view of the inductor according to the first embodiment. FIG. 6 shows a cross-section taken along the line VI-VI of FIG. 5.

In the first embodiment, an active element (not shown) such as an FET is formed on a semiconductor substrate 2 made of a compound such as GaAs, and a surface insulating layer 3 made of silicon nitride is formed on the surface of the semiconductor substrate 2. A ground plate 4 which is connected to the ground potential is provided on the surface insulating layer 2, and an insulating interlayer 5 is formed thereon. The insulating interlayer 3 is made of polyimide or benzocyclobutene (BCB). A line conductor 1 having a predetermined pattern is provided on the insulating interlayer 5. Gold (Au) is used for the material for the line conductor 1. The line conductor 1 is formed by using sputtering or deposition, and the formed line conductor 1 is patterned by using ion milling or lift-off.

In the first embodiment, a portion used as the inductor 100 does not superficially differ from portions used as transmission lines 200. The transmission lines 200, which are linear, originally have a predetermined inductance. A gap 4a is formed under the inductor 100 instead of the ground plate 4 in FIG. 3. Inductance in the gap 4a is treated while it is regarded as the value of a line having a locally lumped parameter.

According to the first embodiment, the inductor 100 in which the influence of a parasitic capacitance is deleted can be obtained.

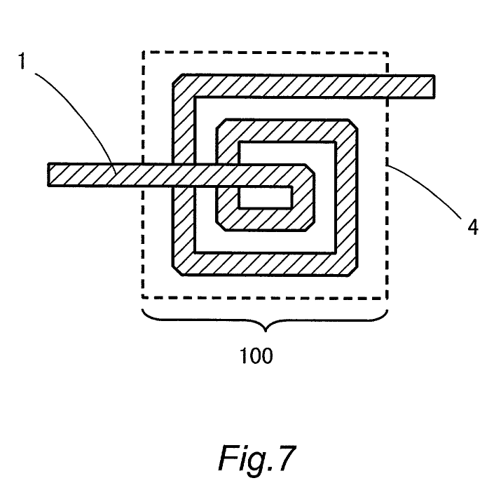

Although the line conductor 1 in the inductor 100 is linear, any shape such as an L-shape which is formed by combining linear shapes can be employed. Not only the meander type shown in FIG. 3 but also the spiral type shown in FIG. 7 can be employed.

FIG. 7 shows a spiral inductor according to a second embodiment of the present invention.

Referring to FIG. 7, a line conductor 1 has a spiral pattern. In the second embodiment, one end of the line conductor 1 is positioned in the center of the spiral pattern. Accordingly, in order that a potential may be led from the one end, the one end must be extended so as to cross portions of the spiral pattern. For this wiring, three-dimensional wiring formed by performing so-called “air bridging”, or a multilayered wiring structure formed by using insulating interlayers can be used. Alternatively, by using a throughhole, the potential can be led from the lower side of the inductor 100. For example, under the spiral, by providing a terminal as a throughhole which is connected to the inductor 100, direct connection using this throughhole can be established.

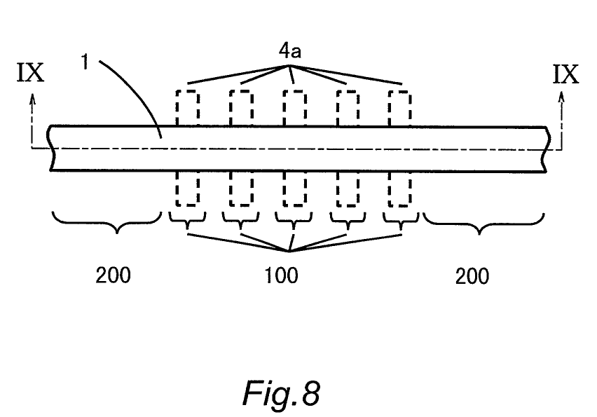

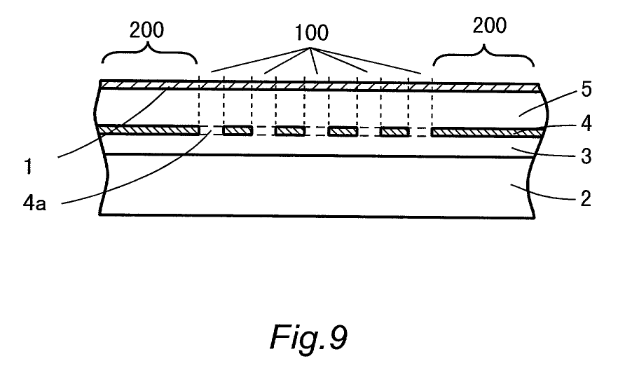

Inductors 100 according to a third embodiment of the present invention is described below referring to FIGS. 8 and 9.

FIG. 8 is a plan view of the inductor according to the third embodiment. FIG. 9 shows a cross-section taken along the line IX-IX of FIG. 8.

In the third embodiment, the inductors 100 have a plurality of gaps 4a. As described above in the first embodiment, the inductor 100 has an electrically lumped constant behavior since it is not opposed to the ground plate 4. Accordingly, by providing the plurality of gaps 4a, a filter is structured.

The third embodiment can be regarded as a transmission line to which a single inductor 100 of the present invention is periodically provided. A filter for a specified frequency is formed by correlation among the interval of the inductors 100, which is a distance in which inductors 100 are connected by a line conductor 1, and the values of the inductors 100.

Although the above embodiments describe a case in which the line conductor 1 is provided as a single layer, the present invention can be applied to a so-called “three-dimensional MMIC” in which a multilayered form of the line conductor 1 is provided, with a multilayered form of the insulating interlayer 5 provided therebetween.

What is claimed is:

1. A high frequency semiconductor device comprising:
a semiconductor substrate;
a ground plate provided on said semiconductor substrate;
at least one insulating interlayer;
a line conductor provided above said ground plate, with said at least one insulating interlayer provided therebetween; and
at least one inductor as a conductive layer connected to said line conductor, said at least one inductor under which at least one gap is formed by removing part of said ground plate.

2. A high frequency semiconductor device according to claim 1, wherein a conductive layer forming said insulator is linear.

3. A high frequency semiconductor device according to claim 1, wherein a conductive layer forming said insulator has a bending form obtained by combining linear shapes.

4. A high frequency semiconductor device according to claim 1, wherein a conductive layer forming said insulator meanders.

5. A high frequency semiconductor device according to claim 1, wherein a conductive layer forming said insulator has a spiral pattern.

6. A high frequency semiconductor device according to claim 5, wherein part of said line conductor is led outward from the spiral pattern by air bridging.

7. A high frequency semiconductor device according to claim 5, wherein part of said line conductor is led outward from the spiral pattern by a multilayered wiring structure in which said line conductor is multilayered, with the insulating interlayers provided therebetween.

8. A high frequency semiconductor device according to claim 5, further comprising at least one throughhole, wherein part of said line conductor in the center of the spiral pattern is led to the lower side of the spiral pattern by said at least one throughhole.

9. A high frequency semiconductor device according to claim 1, wherein the inductors are connected in series to form a filter.

10. A high frequency semiconductor device according to claim 9, wherein:
said line conductor is linear; and
the gaps formed in said ground plate under said line conductor constitute the inductors.

11. A high frequency semiconductor device according to claim 1, wherein said at least one insulating interlayer is made of an insulating resin material.

12. A high frequency semiconductor device according to claim 11, wherein said insulating resin material is one of polyimide and benzocyclobutene.

13. A high frequency semiconductor device according to claim 1, wherein said line conductor is multilayered, with the insulating interlayers provided therebetween.
